(19) United States
(12) Patent Application Publication
(10) Pub. No.: US 2013/0061926 A1
(43) Pub. Date: Mar. 14, 2013

(54) SOLAR CELL ELEMENT AND METHOD FOR PRODUCING THE SAME, AND SOLAR CELL MODULE

(71) Applicants: Manabu Komoda, Omihachiman-shi (JP); Kazuaki Iwameji, Hikone-shi (JP); Kazuyoshi Fujimoto, Yasu-shi (JP)

(72) Inventors: Manabu Komoda, Omihachiman-shi (JP); Kazuaki Iwameji, Hikone-shi (JP); Kazuyoshi Fujimoto, Yasu-shi (JP)

(73) Assignee: KYOCERA CORPORATION, Kyoto-shi, Kyoto (JP)

(21) Appl. No.: 13/699,290

(22) PCT Filed: May 20, 2011
(86) PCT No.: PCT/JP2011/061676

§ 371 Date: Nov. 20, 2012

(30) Foreign Application Priority Data
May 20, 2010 (JP) 2010-116368

(51) Int. Cl. H01L 31/0264; H01L 31/18

(52) U.S. Cl. 136/261; 136/252; 438/57; 257/E31.053

(57) ABSTRACT

Provided is a solar cell element comprising a semiconductor substrate which has a p-type semiconductor region, wherein one or more surface layer-internal regions which have Si—O bonds are formed in the surface layer part of the p-type semiconductor region and a passivation layer is formed on the surface layer-internal regions. Also provided is a solar cell module comprising the solar cell element. A method for producing a solar cell element is further provided, said method comprising: a substrate preparation step for preparing a semiconductor substrate which has a p-type semiconductor region; a surface treatment step for exposing the surface of the p-type semiconductor region to plasma produced using an oxygen-containing gas, and forming surface layer-internal regions which have Si—O bonds in the surface layer part of the p-type semiconductor region; and a layer formation process for forming a passivation layer on the surface layer-internal regions.

### FIELD OF ART

The present invention relates to a solar cell element, a method for producing the solar cell element, and a solar cell module that includes at least one solar cell element.

### BACKGROUND ART

In a solar cell element including a silicon substrate, a passivation film is formed on the surface of the silicon substrate in order to reduce carrier recombination. Silicon nitride film has been studied as a material for use in the passivation film (for example, refer to Japanese Laid-open Patent Publication No. 2009-21358).

There has been, however, the possibility that sufficient passivation effect has not been obtainable, depending on the boundary condition between the passivation film and the silicon substrate. If a silicon nitride film is formed on a silicon substrate having p-type conductivity, because a silicon nitride film generally has a fixed positive charge, at the boundary between a silicon substrate and a silicon nitride film a phenomenon occurs in which there is bending of the band in the direction in which minority carriers increase (band bending). For this reason, it is not possible to reduce the carrier recombination sufficiently, thereby decreasing the short-circuit current and open-circuit voltage of the solar cell element, sometimes leading to a reduction of the photovoltaic conversion efficiency of the solar cell element.

The present invention has an object to provide a solar cell element that reduces the carrier recombination, so as to enhance the photovoltaic conversion efficiency, a method for producing the solar cell element, and a solar cell module.

### DISCLOSURE OF THE INVENTION

A solar cell element according to one embodiment of the present invention is a solar cell element including a semiconductor base that includes a p-type semiconductor region, and a surface layer internal region including Si—O bonds is provided in the surface layer part of the p-type semiconductor region and a passivation layer is provided on the surface layer internal region.

A method for producing a solar cell element according to one embodiment of the present invention includes a substrate preparation step of preparing a semiconductor base that includes a p-type semiconductor region; a surface treatment step of exposing the surface of the p-type semiconductor region to plasma formed using an oxygen-containing gas, and forming a surface layer internal region that includes Si—O bonds in the surface layer part of the p-type semiconductor region; and a layer formation step of forming a passivation layer on the surface layer internal regions.

Moreover, a solar cell module according to one embodiment of the present invention includes the above-noted solar cell element.

According to the above-noted solar cell element, method for producing the solar cell element, and solar cell module, by obtaining a good boundary condition between the p-type semiconductor region and the passivation layer, it is possible to sufficiently reduce carrier recombination. This improves the short-circuit current and open-circuit voltage of the solar cell element, to enable provision of a solar cell element and solar cell module having enhanced photovoltaic conversion efficiency.

### BRIEF DESCRIPTION OF THE DRAWINGS

FIG. 1 is a schematic plan view of an example of a solar cell element according to one embodiment of the present invention, seen from the light-receiving surface side.

FIG. 2 is a schematic plan view of an example of a solar cell element according to one embodiment of the present invention, seen from the non-light receiving surface side.

FIG. 3 is a schematic cross-sectional view cut along the direction of line A-A in FIG. 1, showing an example of a solar cell element according to one embodiment of the present invention, and.

FIG. 4 is a schematic cross-sectional view, with a part of the second surface side in cross-sectional view cut along the direction of line A-A in FIG. 1 shown enlarged, showing an example of a solar cell element according to one embodiment of the present invention.

### EMBODIMENTS FOR PRACTICING THE INVENTION

An embodiment of a solar cell element, a method for production thereof, and a solar cell module according an embodiment of the present invention will be described in detail below, with references made to the drawings.

### <Basic Structure of the Solar Cell Element>

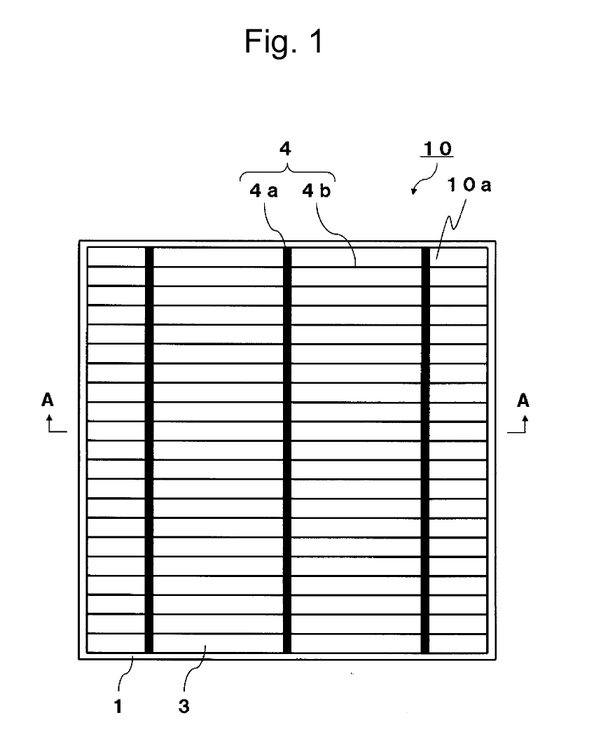

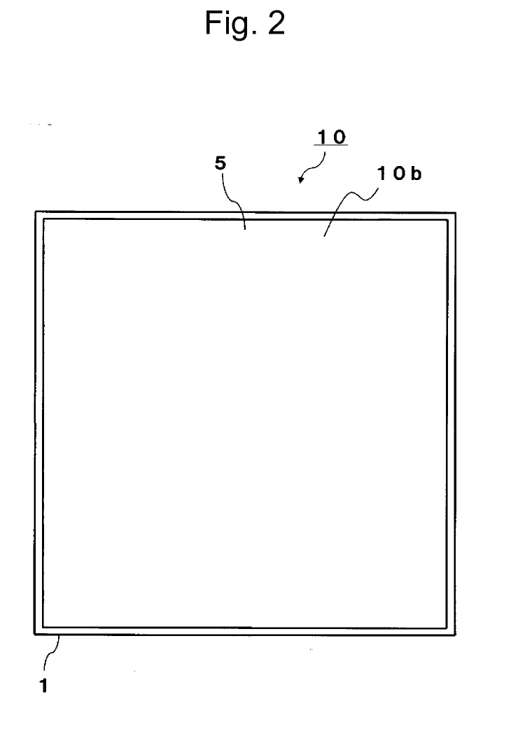

As shown in FIG. 1 to FIG. 3, a solar cell element 10 includes a light-receiving surface (hereafter referred to as a first surface) 10a, into which light enters, and a non-light receiving surface (hereafter referred to as a second surface) 10b corresponding to the rear surface of the first surface 10a. Also, the solar cell element 10 includes, for example, a sheet-like semiconductor base 9 (for example, constituted by a semiconductor substrate 1 that is a semiconductor region of one conductivity type and a reverse conductivity type layer 2 that is the reverse conductivity type semiconductor region provided on the first surface 10a side of the semiconductor substrate 1), an anti-reflection layer 3 provided on a first surface 10a side of the semiconductor base 9 (on the reverse conductivity type layer 2 in the present embodiment) and a passivation layer 7 having, for example, a fixed positive charge provided on the second surface 10b side.

The solar cell element 10 includes a first electrode 4 provided on the first surface 10a side of the semiconductor base 9 and a second electrode 5 provided on the second surface 10b side of the semiconductor base 9.

Moreover, in the solar cell element 10, when the semiconductor substrate 1 has p-type conduction, one or more surface layer internal regions 8 including Si—O bonds is provided in the surface layer part of the second surface 10b side of the semiconductor substrate 1. In this case, the surface layer part refers to the part to a depth of approximately 2 to 10 nm from the surface of the semiconductor substrate 1. The passivation layer 7 is provided on the surface layer internal region 8. Si—O bonds can exist in an inner part by to a depth of at least approximately 10 nm from the surface of the semiconductor substrate 1.

A crystalline silicon substrate such as a monocrystalline silicon substrate or polycrystalline silicon substrate that exhibits one conductivity type (for example, p-type) including, for example, a predetermined dopant element (impurity for controlling the conductivity type) is preferably used as the semiconductor substrate 1. The thickness of the semiconductor substrate 1 is preferably, for example, no greater than 250 μm, and more preferably no greater than 150 μm. Although the shape of the semiconductor substrate 1 is not be particularly limited, as shown in drawings, a square shape when seen in plan-view manner may be preferable from the standpoint of the production method and the case of constituting a solar cell module by arrangement of a large number of solar cell elements. Also, as the semiconductor base 9, a semiconductor other than crystalline silicon-based semiconductor may be used. It is possible to use, for example, semiconductor materials such as thin-film silicon (including at least one of either of amorphous silicon and microcrystal silicon) or silicon-germanium. However, as the semiconductor base 9, the use of crystalline silicon facilitates fabrication, so as to be preferable in view of a production cost, photovoltaic conversion efficiency, and the like.

A passivation layer 7 is made of one or more layers, and at least one or more type of materials selected from silicon nitride, silicon oxide, and aluminum oxide may be used. Specifically, if silicon nitride is used as the passivation layer 7, it is preferable that the semiconductor substrate be subjected to hydrogen passivation by hydrogen that is generated at the time of formation of the silicon nitride.

### <Specific Example of a Solar Cell Element>

A more specific example of a solar cell element will be described below. An example of the use of the crystalline silicon substrate exhibiting p-type conductivity type will be described. When the semiconductor substrate 1 made of a crystalline silicon substrate constituting the semiconductor base 9 is made to exhibit p-type, it is preferable to use, for example, boron or gallium as a dopant element.

A reverse conductivity type layer 2 constituting a semiconductor base 9 is a layer that exhibits a conductivity type that is the reverse of that of the semiconductor substrate 1, and is provided on the first surface 10a side of the semiconductor substrate 1. That is, the reverse conductivity type layer 2 is formed in the surface layer of the semiconductor body 9. If a silicon substrate that exhibits p-type conductivity type is used as the semiconductor substrate 1, the reverse conductivity type layer 2 is formed so as to exhibit n-type conductivity type.

On the other hand, if a silicon substrate that exhibits n-type conductivity type is used as the semiconductor substrate 1, the reverse conductivity type layer 2 is formed so as to exhibit p-type conductivity type. A p-n junction is formed between a p-type conductivity region and an n-type conductivity region. Such a reverse conductivity type layer 2 is formed, for example, by diffusing an impurity such as phosphorus at the first surface 10a side of the silicon substrate 1 if the semiconductor substrate 1 is a silicon substrate exhibiting p-type conductivity type.

Because the anti-reflection layer 3 play a role of reducing the light reflectivity at the desired wavelength region so as to increase the number of photogenerated carriers, the photocurrent density Jsc of the solar cell element 10 can be improved. The anti-reflection layer 3 includes, for example, a silicon nitride film, a titanium oxide film, a silicon oxide film, a magnesium oxide film, an indium tin oxide film, a tin oxide film or a zinc oxide film. The thickness of the anti-reflection layer 3 is arbitrarily selected depending on materials to be used, and may be a thickness that achieves the reflection-free condition with respect to appropriate incident light. In the semiconductor substrate 1 made of, for example, silicon, it is preferable that the refractive index be approximately 1.8 to 2.3, and that the thickness be approximately 500 to 1200 Å. Use of a silicon nitride film for the anti-reflection layer 3 is preferable, because the passivation effect can be obtained as well.

The passivation layer 7 is at least one layer, and at least one type that is selected from, for example, silicon nitride, silicon oxide, and aluminum oxide used as a material thereof, formed at the second surface 10b side of the semiconductor substrate, and having the role of reducing carrier recombination. The passivation layer 7 may be formed with a thickness of approximately 100 to 2000 Å.

A BSF (back surface field) region 6 has the role of reducing the loss of efficiency by carrier recombination in the vicinity of the second surface 10b of the substrate 1, and forms an internal electric field at the second surface 10b side of the semiconductor substrate 1. Although the BSF regions 6 exhibit the same conductivity type as the semiconductor substrate 1, the dopant element in the BSF region 6 has higher concentration than the concentration of majority carrier contained by the semiconductor substrate 1. In this situation, the languages “has higher concentration” refers to having a higher concentration than the carrier concentration attributed to the dopant element for the purpose of achieving one conductivity type in the semiconductor substrate 1. That is, if the semiconductor substrate 1 exhibits p-type conductivity, the SBF region 6 is a p⁺ semiconductor region in which the impurity concentration is higher. By, for example, diffusing a dopant element such as boron or aluminum at the second surface 10b side, the BSF regions 6 may be formed so that the concentration of these dopant elements is approximately 1×10¹⁸ to 5×10²¹ atoms/cm³. It is preferable that the BSF regions 6 be formed over a region having at least a surface area of approximately 0.1 to 10% with respect to the surface area of the passivation layer 7 when seen in plan-view manner.

As shown in FIG. 1, the first electrode 4 includes an output extraction electrode 4a and a plurality of linear collector electrodes 4b. At least a part of the output extraction electrode 4a intersects with the collector electrodes 4b. The output extraction electrode 4a has a width of, for example, approximately 1.3 to 2.5 mm. In contrast, because the collector electrodes 4b have linear shapes and have a width of approximately 50 to 200 μm, they have a smaller width than the output extraction electrode 4a. Also, the collector electrodes 4b are provided so that a plurality of linear electrodes is mutually spaced approximately 1.5 to 3 mm apart. The thickness of such a first electrode 4 is approximately 10 to 40 μm. The first electrode 4 can be formed, for example, by screen printing a conductive paste that includes a metal material such as silver having good electrical conductivity to coat it in a desired pattern, followed by firing.

The second electrode 5 has a thickness of approximately 1 to 10 μm, and is formed over substantially the entire surface of the second surface 10b side of the semiconductor substrate 1. The second electrode 5 can be formed by coating a conductive paste having, for example, silver or aluminum as a main component, followed by firing, or alternatively can be formed by depositing a film using sputtering or vapor deposition. The second electrode 5 that includes an electrical conductivity layer is electrically connected to the semiconductor substrate 1 via the BSF region 6.

The surface layer internal region 8 provided in the surface layer part on the second surface 10b side of the semiconductor substrate 1 has a thickness of approximately 2 to 10 nm, and includes Si—O bonds. By providing a passivation layer 7 on the surface layer internal region 8, it is possible to achieve a sufficient passivation effect. Also, even if a passivation layer 7 made of silicon nitride film is formed on the semiconductor substrate 1 that has p-type conductivity, because of the above-described construction, band bending is reduced, enabling sufficient reduction of recombination, and improvement of the short-circuit current and open-circuit voltage of the solar cell element. In particular, if a passivation layer 7 having a fixed positive charge is used, by providing a surface layer internal region 8 including Si—O bonds, it is possible to reduce the influence of band bending. This is because the existence of Si—O bonds in the surface layer internal region 8, and a deep trap state density at the boundary between the passivation layer 7 and the surface layer internal region 8 is reduced, so that the fixed charge density at the boundary is reduced.

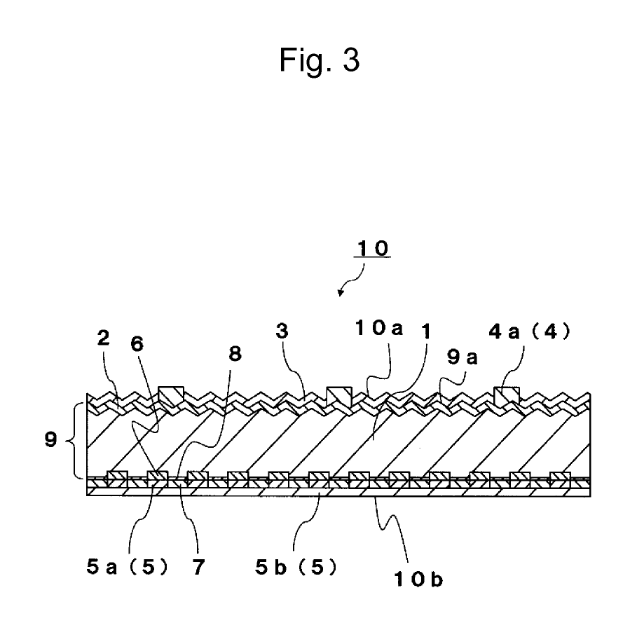

The BSF regions 6 are provided so as to be in a line in the surface layer internal region 8. For example, as shown in FIG. 3, the BSF regions 6 and the surface layer internal regions 8 may be arranged in a regular, alternating manner, and the BSF regions 6 may be provided in the periphery of surface layer internal regions 8 disposed as points, or the surface layer internal regions 8 may be provided in the periphery of BSF regions 6 disposed as points. Additionally, the BSF regions 6 and the surface layer internal regions 8 may be formed so as to overlap.

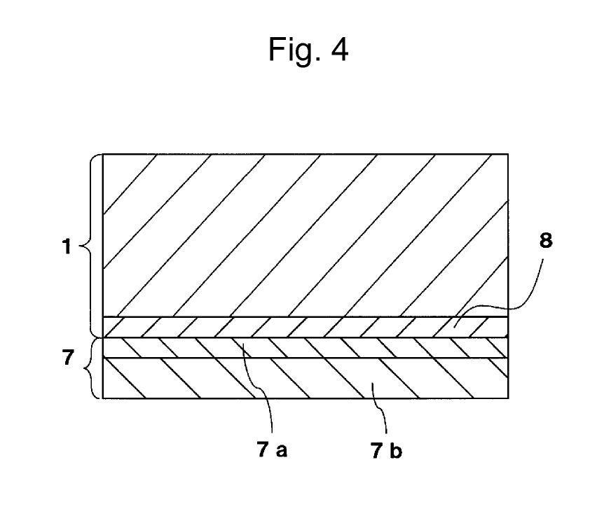

The passivation layer 7 may be constituted by a plurality of layers including at least a first layer 7a and a second layer 7b, for example, as shown in the partially enlarged cross-sectional view of a solar cell element shown in FIG. 4. It is particularly preferable that the first layer 7a that is in contact with the surface layer internal region 8 be made of silicon oxide. For example, a first layer 7a made of silicon oxide having a thickness of approximately 5 to 500 Å can be provided over the semiconductor substrate 1, and a second layer 7b made of silicon nitride or aluminum oxide can be provided thereon. By constituting the passivation layer 7 in this manner, even if there are many dangling bonds at the surface of the semiconductor substrate 1, because a first layer 7a made of silicon oxide is provided, these tend to be made passive, thereby enabling the achievement of a sufficient passivation effect.

### <Method for Producing a Solar Cell Element>

The method for producing a solar cell element 10 will be described, with references made mainly to FIG. 3.

The basic method for producing a solar cell element according to the present embodiment will first be described. In the present embodiment, minimally the following process steps are performed sequentially. First, a base preparation step of preparing a semiconductor base including a semiconductor substrate 1 that is a p-type semiconductor region is performed. Next, a surface treatment process step is performed whereby the surface of the semiconductor substrate 1 is exposed to a plasma formed using a gas that includes oxygen atoms, and surface layer internal regions 8 including Si—O bonds in the surface layer part of the semiconductor substrate 1 are formed. Then, a layer forming process step is performed whereby a passivation layer 7 is formed on the surface layer internal regions 8.

A specific example of the method for producing the solar cell element 10 will next be described. First, the base preparation process step for the semiconductor base 9 will be described. If the semiconductor substrate 1 that mainly constitutes the semiconductor base 9 is a monocrystalline silicon substrate, the pulling method, for example, is used to form the semiconductor substrate and if the semiconductor substrate 1 is made of polycrystalline silicon, the casting method or the like is used to form the semiconductor substrate 1. In the following, the example of using p-type polycrystalline silicon will be described.

First, a polycrystalline silicon ingot is fabricated using, for example, the casting method. Next, the ingot is sliced to a thickness of, for example, 250 μm or less. After that, in order to cleanse the mechanically damaged layer and contaminated layer of the cut surfaces of the semiconductor substrate 1, a very small amount of etching is done of the surface, using a solution of NaOH, KOH, hydrofluoric acid, or fluoronitric acid. After this etching process step, it is further desirable that wet etching be used to form minute structure of unevenness on the surface of the semiconductor base 1. Depending upon the conditions for this wet etching, it is possible to omit the above-described damaged layer removal process step.

Next, an n-type reverse conductivity layer 2 is formed within the surface layer of the first surface 10a side of the semiconductor substrate 1. A reverse conductivity layer 2 such as this is formed by a coating and thermal diffusion method in which P₂O₅ that has been made into a paste is coated onto the surface of the semiconductor substrate 1 and is then subjected to thermal diffusion, by a vapor-phase thermal diffusion method with using phosphorus oxychloride (POCl₃) that has been made into gas state as the diffusion source, by an ion implantation method to directly diffuse phosphorus, or the like. The reverse conductivity layer 2 is formed to a depth of approximately 0.2 to 2 μm, and to have a sheet resistance of approximately 60 to 150 Ω/square. The method for forming the reverse conductivity layer 2 is not limited to the above-noted methods, and may be, for example, with the use of thin-film technology, a hydrogenated amorphous silicon film or a crystalline silicon film that contains a microcrystalline silicon film may be formed. Additionally, an i-type silicon region may be formed between the semiconductor substrate 1 and the reverse conductivity layer 2.

Next, if a reverse conductivity layer 2 is formed on the second surface 10b side, the second surface 10b side only is removed by etching, so as to expose the p-type conductivity region. For example, the reverse conductivity layer 2 is removed by immersing only the second surface 10b side of the semiconductor substrate 1 into fluoronitric acid. After that, the phosphorus glass that becomes attached to the surface of the semiconductor substrate 1 when the reverse conductivity layer 2 is formed is removed by etching. In this manner, by leaving phosphorus glass and removing the reverse conductivity layer 2 formed on the second surface 10b side, the phosphorus glass acts as an etching mask, thereby enabling a reduction in the amount of the reverse conductivity layer 2 removed on the first surface 10a side and in damage incurred.

By the above, it is possible to prepare a semiconductor base 9 including a reverse conductivity layer 2 and a semiconductor substrate 1 that includes a p-type semiconductor region.

Next, the anti-reflection layer 3 is formed. The anti-reflection layer 3 is formed by using, for example, PECVD (plasma-enhanced chemical vapor deposition) method, vapor deposition method, sputtering method or the like. For example, if the anti-reflection layer 3 made of silicon nitride film is formed by PECVD, with a reaction chamber at approximately 500° C., a gas mixture of silane (SiH₄) and ammonia (NH₃) is diluted with nitrogen (N₂) gas, and a plasma is created using glow discharge decomposition so as to cause deposition, thereby forming the anti-reflection layer 3.

Next, surface layer internal regions 8 including Si—O bonds within the surface layer on the second surface 10b side of the semiconductor substrate 1 is formed. When doing this, the surface of the semiconductor substrate 1 is exposed to a plasma formed using a gas that includes oxygen atoms, such as at least one type selected from carbon monoxide, carbon dioxide, oxygen, and nitrous oxide, thereby having a surface treatment of the second surface 10b side of the semiconductor substrate 1, so that the oxygen atoms generated by the decomposition of the above-noted gases are driven into the inside of the semiconductor substrate 1, thereby forming surface layer internal regions 8 including Si—O bonds.

Of the above-noted gases, the use of carbon dioxide gas is particularly preferable, because it facilitates the formation of Si—O bonds. It is preferable that the above-noted gas further include hydrogen. The reason for this is that, by including hydrogen, the Si-Si bonds are broken apart by hydrogen radicals, and oxygen atoms bond at the broken bond positions, thereby improving the rate of formation of Si—O bonds.

The above-noted process step of surface treatment by a plasma is, for example, performed under conditions of a flow rate of 20 to 200 sccm of carbon dioxide, a base temperature of 150 to 300° C., a gas pressure of 10 to 100 Pa, a plasma excitation frequency of 13.56 to 27.12 MHz, a plasma power density of 0.1 to 10 W/cm², and a processing time of 10 to 120 minutes. If the above-noted gas includes hydrogen gas, the flow ratio between the carbon dioxide and the hydrogen can be in the range from 1:2 to 3:1.

Next, a layer formation process step is performed whereby a passivation layer 7 made of a silicon nitride film, a silicon oxide film, or an aluminum oxide film is formed. The passivation layer 7 is formed using PECVD method, ALD (atomic layer deposition) method, sputtering method, or the like. For example, in the case of forming a silicon nitride film using PECVD method, a gas mixture of silane (SiH₄) at 10 to 200 sccm and ammonia (NH₃) at 10 to 500 sccm is used. When this is done, using the conditions of a base temperature of 200 to 500° C., a gas pressure of 5 to 300 Pa, a plasma excitation frequency of 13.56 to 40.68 MHz, and a plasma power density of 0.002 to 1 W/cm² are used and a plasma is created using glow discharge decomposition so as to deposit a silicon nitride film to form a passivation layer 7.

It is preferable, after forming the surface layer internal regions 8 including Si—O bonds, to form a silicon oxide film. The reason for this is that, because oxygen atoms are implanted in the semiconductor substrate 1 at the time of forming the surface layer internal regions 8, even if many dangling bonds are generated at the surface of the semiconductor substrate 1, it is possible to make the surface of the semiconductor substrate 1 passivated by the formation of a silicon oxide film, enabling achievement of sufficient passivation effect.

The silicon oxide film can be formed by atmospheric-pressure CVD method or by the method of making contact with nitric acid vapors or a nitric acid solution. In particular, when the silicon oxide film is formed by causing contact with nitric acid vapors or a nitric acid solution, because plasma processing is not used and also because there is no need to bring the semiconductor substrate 1 to a high temperature, it is possible to reduce the damage imparted to the semiconductor substrate 1. Additionally, it is more appropriate to form silicon oxide films on both surfaces of the semiconductor substrate 1.

Specifically, the formation of the silicon oxide film is done, for example, as follows. By immersing the semiconductor substrate 1 in a nitric acid solution which has at least 60%mass concentration of nitric acid and which has been heated to an appropriate temperature, or by holding the semiconductor substrate 1 in a nitric acid vapor produced by heating a nitric acid solution until it boils, which has at least 60%mass concentration of nitric acid, a silicon oxide film can be formed on the surface of the semiconductor substrate 1. The temperature of the nitric acid solution when immersing into the nitric acid solution can be made, for example, a temperature that is at least 100° C. and slightly lower than the boiling point of the nitric acid solution. In either of the above-noted methods, the time of immersion in the nitric acid solution and the time of holding in the nitric acid vapor can be set as appropriate to be able to form a silicon oxide film having a prescribed thickness.

Next, the first electrodes 4 (output extraction electrodes 4a and collector electrode 4b) and the second electrodes 5 (first layer 5a and second layer 5b) are formed as described below.

The first electrodes 4 are fabricated using a silver paste that contains, for example, a metal powder made of silver, or the like, an organic vehicle, and glass frit. This silver paste is coated onto the first surface of the semiconductor substrate 1, after which it is sintered for several tens of seconds to several tens of minutes at a maximum temperature of 600 to 850° C. The fire-through method is used to form the first electrodes 4, which breaks through the anti-reflection layer 3, on the semiconductor substrate 1. The method used for coating the paste can be screen printing or the like. After coating the paste, the solvent can be vaporized at a prescribed temperature to cause drying.

Next, the formation of the BSF regions 6 will be described. First, apertures are formed in the passivation layer 7. As for the formation of the apertures can be done, for example, points of the passivation layer 7 can be removed at a spacing of 200 μm to 1 mm and a diameter of approximately 50 to 500 μm, by sandblasting method, mechanical scribing method, chemical etching method, or laser method. Their shapes are not particularly limited, and can be, for example, circular, elliptical, or polygonal. The passivation layer 7 can also be formed by a mask so as to achieve a prescribed shape. Then, for example, an aluminum paste that contains aluminum powder and an organic vehicle is applied to inside the apertures of the passivation layer 7. The method used for coating can be screen printing or the like. In this case, after coating the paste, the solvent is vaporized at a prescribed temperature to cause drying, so that the paste does not become attached to other parts during this process.

Next, the semiconductor substrate 1 is fired in a firing furnace for approximately several tens of seconds to several tens of minutes at a maximum temperature of 600 to 850° C., so as to form the BSF regions 6 on the second surface 10b side of the semiconductor substrate 1, and to form the aluminum layer that will served as the first layer 5a of the second electrode 5. In this formation of the electrodes, even if the semiconductor substrate 1 is heated to 600° C. or higher, because the Si—O bonds are stable, the possibility of the surface layer internal regions 8 breaking at the time of heating for electrode formation is small, so that it is possible to achieve sufficient passivation effect.

Next, the second layer 5b of the second electrode 5 is formed by a vacuum deposition method such as sputtering method or vapor deposition method of a high-reflectivity metal such as, for example, silver or aluminum. By an additional thick-film method such as plating or the like, using the second layer 5b as the seed layer, it is possible to achieve a low resistance.

By doing the above, the solar cell element 10 is fabricated.

The present invention is not limited to the above-described embodiment, and can be subjected to many modifications and changes within the scope of the present invention. Although in the above-described embodiments the apertures in the passivation layer 7 are described as being formed beforehand, an aluminum paste that contains glass frit may be formed directly over a prescribed region on the passivation layer 7, and the fire-through method in which high-temperate heat treating is performed may be used to form the BSF regions 6 that break through the passivation layer 7 on the semiconductor substrate 1 so as to form the first layer 5a thereon. Also, in the case of forming points of aluminum paste containing glass frit, a metal paste, which does not allow the fire-through method, such as an aluminum paste and a silver paste can be coated on substantially the entire surface of the second surface 10b side and fired, enabling formation of the second layer 5b on the passivation layer 7.

Additionally, an aluminum layer is formed on the passivation layer 7, using printing method, sputtering method, vapor deposition method or the like, and laser light locally strikes onto the aluminum layer to be melted. This causes the aluminum component to pass through the passivation layer 7, enabling the formation of the BSF regions 6 that make contact and react with the semiconductor substrate 1. That is, LFC (laser fired contacts) method can be used to form the BSF regions 6. When this is done, it is preferable that the BSF regions 6 be formed as points with a spacing of 200 μm to 1 mm and a diameter of approximately 50 to 500 μm, and the aluminum layer formed by the above-noted method is used as the second electrode 5.

The BSF regions 6 may be formed before formation of the passivation layer 7, and boron or aluminum may be diffused in a prescribed region. The boron is diffused by thermal diffusion, using boron tribromide (BBr₃) as the diffusion source, and heating at a temperature of approximately 800 to 1100° C. By using, for example, with the use of thin-film technology, a hydrogenated amorphous silicon film or a crystalline silicon film that contains a microcrystalline silicon film may be formed. Additionally, an i-type silicon region may be formed between the semiconductor substrate 1 and the BSF regions 6.

The sequence of forming the anti-reflection layer 3 and the passivation layer 7 may be the reverse of the above-noted sequence. It is preferable that the semiconductor substrate 1 be cleaned before formation of the anti-reflection layer 3 and the passivation layer 7. This cleaning is preferably done by one of (1) to (3) noted below.

(1) Treatment with hydrofluoric acid.

(2) RCA cleaning (a cleaning method developed by RCA in the US, in which cleaning is done by high-temperature, high-concentration sulfuric acid/hydrogen peroxide water, dilute hydrofluoric acid (room temperature), ammonia water/hydrogen peroxide water, or hydrochloric acid/hydrogen peroxide water or the like), followed by treatment with hydrofluoric acid.

(3) SPM (sulfuric acid/hydrogen peroxide/water mixture) cleaning, followed by treatment with hydrofluoric acid.

Even if the BSF regions 6 and the low-resistivity metal electrodes, which are the electrode layer formed thereon, are formed in the shape of a ladder, by using a high-reflectivity backing sheet on the reverse surface when laminating, it is possible to achieve a highly functional reverse-surface reflective structure. If the planar shape of the low-resistivity metal electrode is made the ladder shape, which is similar to the first electrodes 4, a part of the low-resistivity metal electrode may be a shape that makes contact with the semiconductor substrate 1, and the BSF regions 6 may be provided only on the contacting part.

In an arbitrary process step performed after the formation of the passivation layer 7, an annealing treatment using a gas that contains hydrogen can be done to further lower the recombination rate at the reverse surface.

Also, when a solar cell element is fabricated in which the anti-reflection layer 3 is a silicon nitride film and which uses a semiconductor substrate 1 having n-type conductivity, because the reverse conductivity layer 2 exhibits p-type conductivity, the above-noted effect can be expected by forming the anti-reflection layer 3 after forming the surface layer internal regions 8 that include Si—O bonds on the first surface 10a side.

Although the description has been for the example in which a solar cell element is used in which electrodes are formed on both surfaces of the semiconductor substrate 1, application is also possible to a back-contact type of solar cell element in which electrodes are formed only on one surface.

Also, although the solar cell element of the present embodiment has been described for the example of fabricating using a semiconductor substrate as the semiconductor base, the semiconductor base is not limited to being sheet-shaped, and in a solar cell of the ball solar type, for example, application is possible to a semiconductor base that is not sheet-shaped, such as one that is spherical.

### <Solar Cell Module>

In a solar cell module of the present embodiment, for example, one solar cell element 10 or a plurality of solar cell elements 10 electrically connected in series by a conductor can be sealed onto a supporting substrate of glass, resin, metal, or the like, using a filling material such as EVA (ethylene vinyl acetate), which has good resistance to humidity. In this case, a frame made of metal, resin, or the like may be provided in the area surrounding the supporting substrate.

### EXAMPLES

The following will be a description of specific examples. First, a large number of polycrystalline silicon substrates having a thickness of approximately 200 μm were prepared as the semiconductor substrate 1. The polycrystalline silicon substrates that were used had been previously doped with boron so as to exhibit p-type conductivity.

RIE (reactive ion etching) method was used to form an uneven structure 9a as shown in FIG. 3 on the first surface 10a side of each of the prepared polycrystalline silicon substrates. Next, phosphorus atoms were diffused, so as to form an n-type reverse conductivity layer 2 having a sheet resistance of approximately 90 Ω/square. The reverse conductivity layer 2 formed on the second surface 10b side was removed using a fluoronitric acid solution, after which phosphorus glass that remained on the reverse conductivity layer 2 was removed with a hydrofluoric acid solution. Next, plasma CVD was used to form an anti-reflection layer 3 made of a silicon nitride film on the first surface 10a side, and plasma CVD was used to form a passivation layer 7 made of a silicon nitride film on the second surface 10b side.

Then, a silver paste was coated onto the first surface 10a side in the linear pattern shown in FIG. 1, and an aluminum paste is coated onto the second surface 10b side in a dot pattern with approximately 500 μm spacing and diameters of 150 μm. After that, these paste patterns were fired to form the first electrodes 4 and the BSF regions 6 such as shown in FIG. 3. With the fire through method, each of the first electrodes 4 and the BSF regions 6 was made contact with the semiconductor substrate 1.

Finally, as the second electrode 5, aluminum was formed, using vapor deposition method, on substantially the entire surface of the second surface 10b side, to a thickness of 10 μm.

In each of the examples 1 to 4, before forming the passivation layer 7 on the second surface 10b side, surface treatment was done by exposing the second surface 10b side of the semiconductor substrate 1 to a plasma that was produced using a gas that contains carbon dioxide. The surface treatment process step that was performed at that time was done under the conditions of a carbon dioxide flow rate of 100 sccm, a base temperature of approximately 200° C., a gas pressure of approximately 40 Pa, a plasma excitation frequency of 13.56 MHz, plasma power densities of 0.1 W/cm² (in the case of example 1), 0.3 W/cm² (in the case of example 2), 0.5 W/cm² (in the case of example 3), and 1.0 W/cm² (in the case of example 4), and a processing time of 30 minutes.

In the examples 5 to 8, before forming the passivation layer 7 on the second surface 10b side, surface treatment was done by exposing the second surface 10b side of the semiconductor substrate 1 to a plasma that was produced using a gas that contains carbon dioxide and hydrogen. The surface treatment process step that was performed at that time was done under the conditions of a carbon dioxide flow rate of approximately 100 sccm, a hydrogen flow rate of approximately 100 sccm, a base temperature of approximately 200° C., a gas pressure of approximately 50 Pa, a plasma excitation frequency of 13.56 MHz, plasma power densities of 0.1 W/cm² (in the case of example 5), 0.3 W/cm² (in the case of example 6), 0.5 W/cm² (in the case of example 7), and 1.0 W/cm² (in the case of example 8), and a processing time of 20 minutes.

In the comparative examples, the passivation layer 7 was formed on the second surface 10b side without performing the above-noted surface treatment process step.

For each of the comparative examples 1 to 8, the solar cell element output characteristics (short-circuit current Isc, open-circuit voltage Voc, curve factor FF (fill factor), and photovoltaic conversion efficiency) were measured and evaluated. The measurements of these characteristics were performed in accordance with JIS C8913, under the conditions of an AM (air mass) of 1.5 and radiation of 100 mW/cm².

The second electrode 5 and the second surface 10b side after removal of the passivation film 7 were analyzed in the depth (thickness) direction of the semiconductor substrate 1, using an X-ray electron photospectroscopic apparatus (XPS (X-ray photoelectron spectroscopy) using a Quantera SXM manufactured by PHI), and the existence or non-existence of Si—O bonds was evaluated. With regard to the existence and non-existence of Si—O bonds, the judgment as to whether Si—O bonds existed within the semiconductor substrate 1 was performed by subtracting the background attributed to Si—O bonds in the outermost surface of the semiconductor substrate 1 from the spectrum detected up to a depth of 10 nm from the outermost surface of the semiconductor substrate 1. The solar cell element output characteristics of examples 1 to 8 are shown as values that were normalized, with the comparative example taken as 100. The results of the measurement and evaluation of each example are shown in Table 1.

TABLE 1

| | Plasma | Existence | | | | Photo- |
|---|---|---|---|---|---|---|
| | power | of | | | | voltaic |
| | density | Si—O | | | | conversion |
| | (W/cm²) | Bonding | Isc* | Voc* | FF* | efficiency* |
| Example 1 | 0.1 | Yes | 102 | 101 | 100 | 103 |
| Example 2 | 0.3 | Yes | 101 | 103 | 101 | 105 |
| Example 3 | 0.5 | Yes | 101 | 104 | 100 | 105 |
| Example 4 | 1.0 | Yes | 101 | 101 | 100 | 102 |
| Example 5 | 0.1 | Yes | 102 | 103 | 100 | 105 |
| Example 6 | 0.3 | Yes | 102 | 104 | 101 | 107 |
| Example 7 | 0.5 | Yes | 102 | 101 | 101 | 104 |
| Example 8 | 1.0 | Yes | 101 | 101 | 101 | 103 |
| Comparative | — | No | 100 | 100 | 100 | 100 |
| Example | | | | | | |

*Characteristics normalized, with the comparative example taken as 100.

Although in all the examples 1 to 8 the existence of Si—O bonding was confirmed inside of the surface layer on the second surface 10b side of the semiconductor substrate 1, in the comparative example the existence of Si—O bonding could not be confirmed. Moreover, it was confirmed that all the examples 1 to 8 had higher output characteristics than the comparative example.

### DESCRIPTION OF THE REFERENCE SYMBOLS

1 Semiconductor substrate (p-type semiconductor region)
2 Reverse conductivity type layer
3 Anti-reflection layer
4 First electrode
   4a Output extraction electrode
   4b Collector electrode
5 Second electrode
   5a First layer
   5b Second layer
6 BSF region
7 Passivation layer
   7a First layer
   7b Second layer
8 Surface layer internal region
9 Semiconductor base
10 Solar cell element
   10a First surface
   10b Second surface

1. A solar cell element, comprising:
a p-type semiconductor substrate comprising a front surface for serving as a light-receiving surface and a back surface opposite to the front surface,
first regions in the back surface comprising Si—O bonds; and
a passivation layer on the p-type semiconductor regions.

2. The solar cell element according to claim 1, further comprising:
second regions in the back surface, comprising p⁺-type semiconductor, and
a conductive layer on the second regions.

3. The solar cell element according to claim 2, wherein the first regions and the second regions are arranged alternately.

4. The solar cell element according to claim 1, wherein the p-type semiconductor substrate comprises crystalline silicon.

5. The solar cell element according to claim 1, wherein the passivation layer comprises a fixed positive charge.

6. The solar cell element according to claim 1, wherein the passivation layer comprises at least one selected from silicon nitride, silicon oxide, and aluminum oxide.

7. The solar cell element according to claim 1, wherein the passivation layer comprises a plurality of sub-layers.

8. The solar cell element according to claim 7, wherein the passivation layer comprises a silicon oxide sub-layer that is in contact with the second regions.

9. The solar cell element according to claim 8, wherein the passivation layer further comprises a silicon nitride sub-layer or an aluminum oxide sub-layer on the silicon oxide sub-layer.

10. A method for producing a solar cell element, the method comprising:
preparing a p-type semiconductor substrate;
first regions that each comprises Si—O bonds in the p-type semiconductor substrate by exposing a surface of the first region to plasma of an oxygen-containing gas; and
forming a passivation layer on the first regions.

11. The method according to claim 10, wherein the passivation layer comprises a fixed positive charge.

12. The method according to claim 10, wherein the oxygen-containing gas further comprises hydrogen.

13. A solar cell module comprising a solar cell element according to claim 1.

14. The method according to claim 1, wherein each of first regions has a thickness of 2 to 10 nm.
